(19) United States
(12) Patent Application Publication
(10) Pub. No.: US 2014/0233297 A1
(43) Pub. Date: Aug. 21, 2014

(54) Graphene Ferroelectric Device and Opto-Electronic Control of Graphene Ferroelectric Memory Device

(71) Applicant: NATIONAL UNIVERSITY OF SiINGAPORE, Singapore (SG)

(72) Inventors: Barbaros Ozyilmaz, Singapore (SG); Orhan Kahya, Singapore (SG); Chee Tat Toh, Singapore (SG); Manu Jaiswal, Singapore (SG); Surajit Saha, Singapore (SG)

(21) Appl. No.: 14/346,477

(22) PCT Filed: Oct. 1, 2012
(86) PCT No.: PCT/SG2012/000366

§ 371 Date: Mar. 21, 2014

Related U.S. Application Data
(60) Provisional application No. 61/540,593, filed on Sep. 29, 2011.
(60) Provisional application No. 61/569,357, filed on Dec. 12, 2011.

(51) Int. Cl. G11C 11/22; H01L 43/02

(52) U.S. Cl. CPC G11C 11/223; H01L 43/02
USPC 365/145; 257/29

(57) ABSTRACT

In accordance with an embodiment of the invention, there is provided a graphene ferroelectric device. The device comprises a graphene transistor channel and a ferroelectric gate of the graphene transistor channel, the ferroelectric gate comprising a linear polarization at a first applied gate voltage less than a threshold voltage, and a hysteretic polarization at a second applied gate voltage greater than the threshold voltage. The device may be configured to undergo optical switching of the graphene transistor channel between a high resistance state and a low resistance state in response to photoillumination of the device.

### RELATED APPLICATIONS

This application claims the benefit of U.S. Provisional Application No. 61/540,593, filed on Sep. 29, 2011, and claims the benefit of U.S. Provisional Application No. 61/569,357, filed on Dec. 12, 2011. The entire teachings of the above applications are incorporated herein by reference.

### U.S. GOVERNMENT SUPPORT

This invention was made with U.S. government support under Grant No. N62909-10-1-7051 from the U.S. Office of Naval Research Global. The U.S. government has certain rights in the invention.

### BACKGROUND OF THE INVENTION

Since the first isolation of graphene [1] in 2004, there has been an enormous amount of research done to investigate its properties. Graphene based field effect transistors (FET's) have a very high potential for electronics, especially in terms of high speed, flexibility and transparency. 100 Ghz transistors made of epitaxial graphene have already been shown by IBM [2], which is a speed beyond the theoretical upper limit for transistors using SiO₂. Samsung has developed a touch screen using graphene as a transparent top conductor [3]. Ahn et al., also showed a flexible and transparent transistor using graphene [4]. There are a number of companies investing in graphene, and commercial products using graphene are expected to be produced.

Graphene can be quickly integrated into the FRAM (Ferroelectric Random Access Memory) concept, which is not very commonly used, although there is a growing interests in FRAM's. The key advantages of the FRAM are high data access time, low power consumption and high data reliability. High access times offer developers the ability to use FRAM's as cache (RAM) memories, so developers have the freedom to dynamically partition memory between cache (RAM), data storage and code space. Intel is working on a polymeric ferroelectric random access memory (PFRAM), in which the memory cells will be stacked on top of each other layer by layer. This method will decrease the device area and the production costs.

A non-volatile graphene-ferroelectric memory was developed in 2009 [5][8]. This memory comprises a graphene FET covered with an organic ferroelectric layer P(VDF-TrFE). By applying a gate bias on the ferroelectric, high and low resistance states are switched in graphene due to the electric dipole induced by the ferroelectric thin film. This switching is non-volatile because the electric dipoles in the ferroelectric film are non-volatile.

As a one-atom-thick single crystal, graphene's electronic properties [9] are closely related to its supporting substrates. SiO₂ provides excellent optical contrast, the key in discovering graphene by micromechanical exfoliation, but with critical drawbacks, such as surface roughness, high concentration of surface impurity charges, surface optical phonons, hydrophilic surface properties, and low dielectric constant (κ_{SiO2}=3.9). Such drawbacks not only limit the carrier mobility but also the dielectric gating strength by the maximum polarizability Pₘₐₓ=∈₀κ_{SiO2}Eₘₐₓ≈1.7 μC/cm², where Eₘₐₓ≈0.5V/nm is the breakdown field of SiO₂. Substantial progress in replacing SiO₂ has already been made, such as significant mobility enhancement of single-layer graphene on boron nitride [3], and non-volatile polymer (top) gating of single-layer graphene [5,10]. However, efforts in this direction are in general constrained by the difficulty of exfoliating and identifying in particular single and bilayer graphene on different substrates. The rapid progress in copper-based chemical-vapor deposition methods (Cu-CVD) has now made wafer-scale graphene synthesis and graphene transfer feasible both for single-layer graphene (SLG) [3,11] and bilayer graphene (BLG) [12], providing great advantages in substrate engineering of graphene for exploring new physics and functionalities [5, 13-17]. With respect to substrates, ferroelectric materials are unique both in non-volatile gating [5] and high polarizability up to 100 μC/cm² (6×10¹⁴ cm⁻² in charge density) [18], 60 times larger than SiO₂. With such high gating strength, it is possible to heavily dope graphene beyond the linear band dispersion regime (˜1 eV) and reach the van Hove singularities [19]. Such high doping, which in contrast to electrolyte gating [20] is gate-tunable even at liquid-helium temperature, may also be of great importance for verifying the recent theoretical prediction of strong electron-phonon interactions and high-temperature superconductivity in graphane and related materials [21]. For graphene electronics, this level of gating strength may enable the opening of a sizeable non-volatile bandgap up to ˜300 meV [22] in bilayer graphene field effect transistors [23]. This may be important not only for achieving high current on-off ratio (such as >10⁴ for logic operations) but also for improving ΔR/R for memory device applications. Equally importantly, it can significantly reduce the switching voltage to below 1V while exceeding the highest doping by SiO₂ gating (10¹³ cm⁻²) [7].

### SUMMARY OF THE INVENTION

In accordance with an embodiment of the invention, there is provided a graphene ferroelectric device. The device comprises a graphene transistor channel and a ferroelectric gate of the graphene transistor channel, the ferroelectric gate comprising a linear polarization at a first applied gate voltage less than a threshold voltage, and a hysteretic polarization at a second applied gate voltage greater than the threshold voltage.

In further, related embodiments, the ferroelectric gate may comprise lead zirconate titanate, such as Pb(Zro_{0.3} Ti_{0.7})O₃. The threshold voltage may comprise about 1 V, i.e., an electric field of about 3 MV/m. The graphene transistor channel and the ferroelectric gate may comprise a transistor at the first applied gate voltage less than the threshold voltage and may comprise a non-volatile memory at the second applied gate voltage greater than the threshold voltage. The graphene transistor channel and the ferroelectric gate may comprise a transistor at the first applied gate voltage less than the threshold voltage, the graphene transistor channel and the ferroelectric gate being configured to control at least one memory array. The memory array may comprise at least one other graphene transistor channel and a ferroelectric gate of the other graphene transistor channel, the ferroelectric gate of the other graphene transistor channel comprising lead zirconate titanate, the at least one other graphene transistor channel and ferroelectric gate comprising a non-volatile memory at the second applied gate voltage greater than the threshold voltage. The graphene transistor channel and the at least one other graphene transistor channel may be included in an array of a plurality of graphene transistor channels on a ferroelectric substrate. The device may be configured to operate as a sensor.

In further, related embodiments, at least a portion of the device may be transparent. At least a portion of the device may be flexible. The device may comprise a flexible and transparent substrate. The graphene transistor channel may comprise a single layer of graphene. The device may comprise an on/off current ratio of at least about 10. The device may be configured to be dynamically switched by a gate bias voltage between operating as a transistor and operating as a non-volatile memory.

In further, related embodiments, the device may be configured to undergo optical switching of the graphene transistor channel between a high resistance state and a low resistance state in response to photoillumination of the device. The device may further comprise a polymer electrolyte layer. The device may be configured to enter a reversible resistance state in response to photoillumination. The photoillumination may comprise light of a wavelength from the group consisting of an ultraviolet wavelength, a visible wavelength and an infrared wavelength. A resistance of the graphene transistor channel may be configured to change in response to a wavelength of photoillumination of the device. The resistance of the graphene transistor channel may be further configured to return to a low resistance state in response to an applied gate voltage. The device may comprise a device from the group consisting of: an optically switchable non-volatile memory; a broadband wavelength detector and an optical-to-electrical data convertor.

In another embodiment according to the invention, there is provided a method of controlling the resistance state of a memory device. The method comprises exposing: at least one first selected element of the memory device, the at least one first selected element comprising at least one first graphene ferroelectric device, to photoillumination of a first selected wavelength, thereby performing a write operation of an on resistance state of the memory device. The at least one first graphene ferroelectric device comprises a first graphene transistor channel and a first ferroelectric gate of the first graphene transistor channel, the first ferroelectric gate comprising lead zirconate titanate. The method further comprises, while exposing the at least one first selected element to the photoillumination of the first selected wavelength, protecting at least one second selected element of the memory device from exposure to the photoillumination at the first selected wavelength, the at least one second selected element comprising at least one second graphene ferroelectric device comprising a second graphene transistor channel and a second ferroelectric gate of the second graphene transistor channel, the second ferroelectric gate comprising lead zirconate titanate; and exposing the at least one second selected element of the memory device to photoillumination of a second selected wavelength, while protecting the at least first selected element from exposure to the photoillumination of the second selected wavelength, thereby achieving an off resistance state of the memory device.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1A is a series of graphs showing resistance of graphene versus applied back gate voltage for a device in accordance with an embodiment of the invention.

FIG. 1B is a set of graphs showing polarization curves of PZT, for a device in accordance with an embodiment of the invention.

FIG. 2 is a diagram of a graphene ferroelectric device in accordance with an embodiment of the invention.

FIG. 3 is a schematic diagram of a graphene device in accordance with an embodiment of the invention, in two-terminal configuration.

FIG. 4 is a graph showing room temperature polarization measurements of a PZT substrate, in accordance with an embodiment of the invention.

FIG. 5A is a graph showing resistance versus back gate voltage before addition of a polymer electrolyte in dark and under white light photo-illumination, in accordance with an embodiment of the invention.

FIG. 5B is a graph showing resistance versus back gate voltage (in dark) before and after addition of a polymer electrolyte, in accordance with an embodiment of the invention.

FIG. 6A is a graph showing resistance versus back gate sweep for a graphene/PZT device in the dark and under photo-illumination of three different wavelengths (Red: 635 nm; Green: 565 nm; and Blue: 466 nm), in accordance with an embodiment of the invention.

FIG. 6B is a graph showing graphene carrier concentration versus V_{BG} in dark and under photoillumination of three different wavelengths (Red: 635 nm; Green 565 nm; and Blue 466 nm), extracted from the data of FIG. 6A, in accordance with an embodiment of the invention.

FIG. 6C is a graph showing resistance versus time during pulsed photo-illumination (of three different wavelengths, viz., Red: 635 nm; Green: 565 nm; and Blue: 466 nm) of a device in accordance with an embodiment of the invention.

FIG. 6D is a graph showing gate current versus time-during-pulsed photo-illumination (of three different wavelengths, viz., Red: 635 nm; Green: 565 nm; and Blue: 466 nm) of a device in accordance with an embodiment of the invention.

FIGS. 7A and 7B are schematic diagrams illustrating the concept of optically programmable graphene/PZT memory devices in accordance with an embodiment of the invention.

### DETAILED DESCRIPTION OF THE INVENTION

A description of example embodiments of the invention follows.

In accordance with an embodiment of the invention, there is provided a device that can be used as a transistor and a memory simultaneously. This device comprises a graphene field effect transistor (GFET), gated with a special ferroelectric material. A graphene transistor channel has controllable resistance states that are used as binary zeroes and ones. This transistor can be used as a memory, if the ferroelectric is intentionally polarized in a non-volatile manner. A ferroelectric material such as Pb(Zr_{0.3}Ti_{0.7})O₃ (which is a type of lead zirconate titanate, called “PZT” herein) has a linear polarization at low gate voltages. At higher gate voltages it exhibits a large remnant polarization. By taking advantage of this property, a transistor gated with PZT can be used as a normal transistor which operates at low voltages, and if it is gated with higher voltage values it can be used a non-volatile memory. The dielectric constant of the ferroelectric material is very high compared to conventional dielectric materials that reduce the operating voltage dramatically. In other words, the ferroelectric gated transistors do not require high voltage for operation, because of the ferroelectric's high dielectric constant.

Typical memory devices include transistors to control the memory array. An embodiment according to the present invention provides a way of making memory-transistor combinations, because in terms of production, an embodiment according to the invention allows a device in which there is no difference between making a transistor or a memory.

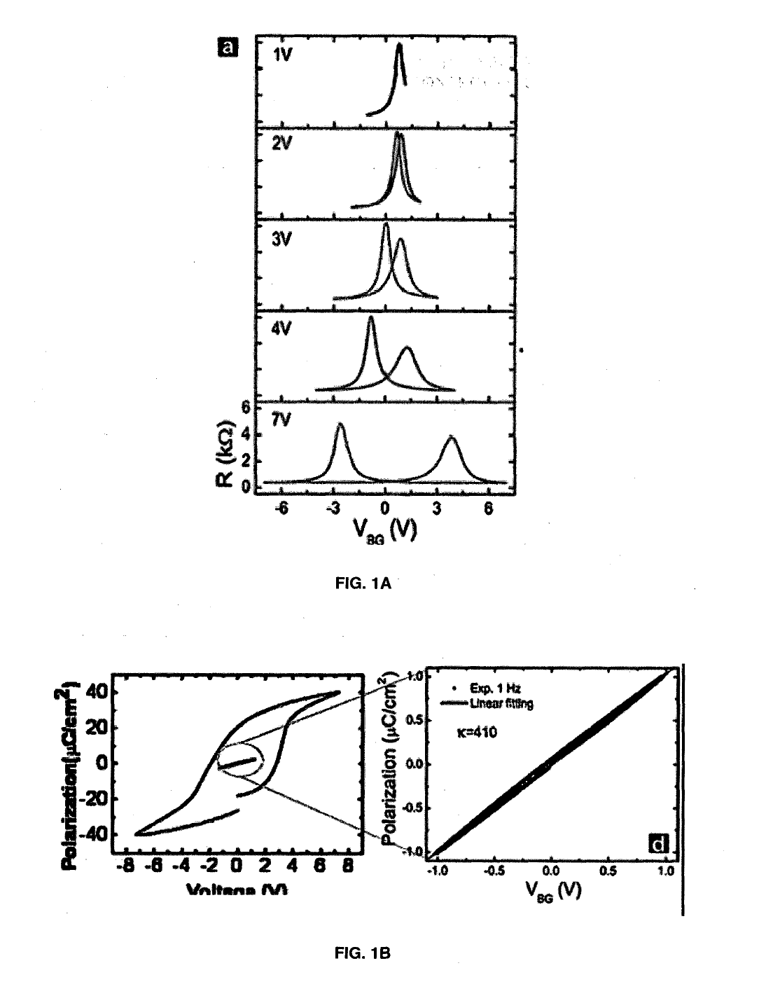

In accordance with an embodiment of the invention, in order to be able to realize this transistor-memory duality, a special ferroelectric is used as a gate material, such as a type of lead zirconate titanate (PZT), in particular Pb(Zr_{0.3}Ti_{0.7})O₃ (see FIG. 1B). FIG. 1A is a series of graphs showing resistance of graphene versus applied back gate voltage for a device in accordance with an embodiment of the invention; and FIG. 1B is a set of graphs showing polarization curves of PZT, for a device in accordance with an embodiment of the invention. Pb(Zr_{0.3}Ti_{0.7})O₃ acts like a traditional gate dielectric (see FIG. 1B) when the applied gate bias is low. Such a transistor works with a very low operating gate voltage. For higher gate voltages the device begins to have a remnant polarization after each sweep. So the resistance versus gate voltage curve of the graphene becomes a double peak structure as shown in FIG. 1A. In order to use this device as a non-volatile memory, a high voltage (for example, above 2V) is applied, and after the voltage has been applied the resistance of the graphene will be switched to either a low or high resistance state and will stay there permanently after the power is switched off.

In accordance with an embodiment of the invention, the ultra-high dielectric constant (κ) of PZT in the linear dielectric regime allows graphene field effect transistors to be switched on and off within ±1V (see first graph in FIG. 1A). Beyond the linear regime (for example, V_{BG}>1.1V), the polarization of PZT leads to a pronounced hysteresis in R vs. V_{BG}. That can be utilized to allow the device to function as a non-volatile memory (see second through fifth graphs in FIG. 1A).

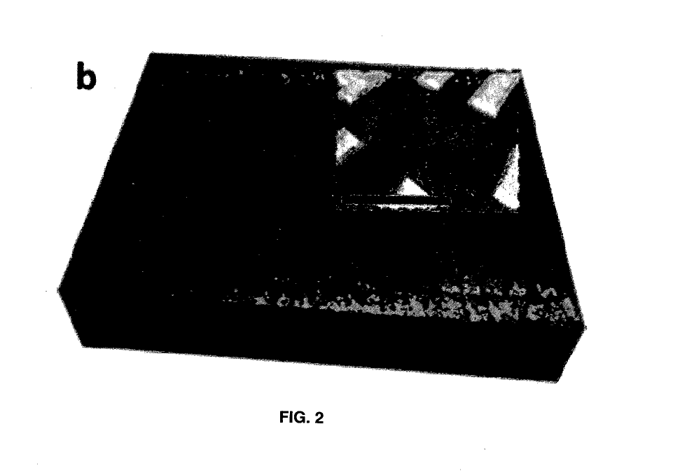

FIG. 2 is a diagram of a graphene ferroelectric device in accordance with an embodiment of the invention. Graphene (hexagonal layer) is shown laying on ferroelectric PZT.

In accordance with an embodiment of the invention, the wafer-scale patterning and device operations of graphene-ferroelectric field effect transistors (GFeFETs) on PZT substrates have been demonstrated, integrating both transistor and non-volatile memory functionalities on the same chip by controlling the local ferroelectric polarization magnitude. In the linear regime of PZT, ultra-low-voltage operations of GFeFETs within ±1V have been demonstrated, which permits the GFeFETs to be used as controlling transistors for addressing and reading/writing of memory unit cells. After polarizing PZT, the hysteretic switching of GFeFETs is ideal for ultra-fast non-volatile data storage.

In conventional flash memories, dynamic random-access memories (DRAMs) or any other memories there is a need for transistors to control the memory arrays. An embodiment according to the present invention provides that transistors and memories can be manufactured side by side on the same chip based on the same substrate. There is no difference between making a transistor or memory, which can be used in a new device architecture in which transistors are put into the memory arrays, instead of in separate compartments as in the conventional architecture.

An embodiment according to the present invention can be used in sensors that record data. Each sensor unit can comprise a transistor, a memory array and a sensor. The memory transistor combination can be produced more easily and less expensively than prior devices, using an embodiment according to the present invention.

In an embodiment according to the present invention, the thickness of the PZT film may be less than 300 nm. At this thickness PZT is transparent and it is reported to be flexible as well [9]. Graphene, a single sheet of a carbon layer, is known to be transparent and flexible. In accordance with an embodiment of the present invention, a novel transparent and flexible transistor can be made by using these two materials (PZT and graphene).

In accordance with an embodiment of the invention, a logic cell that can be used as memory and transistor simultaneously can be used to provide a device that has a dynamic memory over transistor ratio. When there is a need for high data storage, this ratio can be increased, and when there is a need for a high speed this ratio can be decreased. Furthermore, an embodiment according to the invention may decrease production costs because both memory and the transistors can be produced by the same facility. An embodiment according to the invention provides a universal logic cell that can be used as a transistor, non-volatile memory and cache (RAM). Such a device may be used in a circuit architecture that fully benefits from the two different functionalities of each cell. With such a new architecture, cell blocks, like the page system in the NAND-flash memory, can be dedicated to memory-functions by increasing the gate bias, or can be dedicated to transistor functions by decreasing the gate bias. Graphene can increase the speed of the transistors to more than 100 GHz, and may give flexibility to the whole device.

An embodiment according to the invention is able to take advantage of graphene's unique properties as a FET channel material, such as high mobility (20,000 cm²/V*s) [7]. An embodiment according to the invention is also able to take advantage of the high dielectric constant of the ferroelectric material to decrease the operating voltage and the power consumption (in the linear dielectric regime). Further, an embodiment according to the invention is able to take advantage of the ferroelectric's two different dielectric regimes (linear and hysteric), and combines non-volatile memory and transistor properties in one device. An embodiment according to the invention provides the ability for there to be no difference in making a transistor or memory, so that devices which comprise both transistor and memory cells can be produced by one method.

An embodiment according to the invention provides a device that can be used in all electronic devices as a non-volatile memory and transistor. It can be used as a transparent, flexible memory and transistor. It can be used in sensor circuits, which may need flexibility, transparency or high speed. It can be used in memories where there is a need of transistors to control the memory. An embodiment according to the invention provides the ability for there to be no difference between transistor and memory, so that production of a memory will be easier.

Intrinsically, graphene has a low on/off current ratio, such as a ratio of about 20. This is a disadvantage in the transistor application. However, in accordance with an embodiment of the invention, there are many ways to open up a band gap in graphene that can lead to high on/off current ratios, such as about 10⁵ or greater. One way is to make graphene be very short in one dimension; this confinement will lead to a band gap. Another way is to break the interlayer symmetry in bilayer graphene, which will lead to a band gap as well.

In one embodiment according to the invention, multilayer graphene FETs may be stacked on top of each other.

In another embodiment according to the invention, a flexible and transparent substrate may be used, and the entire device may be transparent and flexible.

In accordance with an embodiment of the invention, there are provided Cu-CVD single-layer and bilayer graphene field effect transistors on ferroelectric Pb(Zr_{0.3}Ti_{0.7})O₃ substrates. In a study in accordance with an embodiment of the invention, transistor and non-volatile memory operations have been realized by controlling PZT polarization magnitude. The ultra-high dielectric constant (κ) of PZT in the linear dielectric regime allows graphene field effect transistors to be switched on and off within ±1V with maximum doping exceeding 10¹³ cm⁻². After polarizing PZT, the switching of graphene field effect transistors are characterized by a pronounced resistance hysteresis, ideal for ultra-fast non-volatile memory. Large-scale graphene used in a study in accordance with an embodiment of the invention was synthesized by the CVD method on pure copper foils [3,11]. By controlling the post-growth annealing time, graphene with high bilayer coverage of up to 40%, ideal for comparing the performance of both systems, was synthesized. Subsequently, CVD graphene was transferred to 360 nm PZT, using the method introduced by Li et al. [24,25]. Standard e-beam patterning and metallization was used to fabricate 3 μm size graphene ferroelectric graphene field effect transistors (GFeFETs). The GFeFETs were then electrically characterized from room temperature (RT) to 3K in vacuum in a four-contact configuration using lock-in amplifiers.

In a study in accordance with an embodiment of the invention, the surface morphology of PZT thin films was measured by atomic force microscopy (AFM). PZT has periodic thickness variations of ˜30 nm at a typical width of 35 μm. These are seen as stripes in optical microscopy. Cu-CVD graphene transferred on PZT shows selective enhancement in Raman 2D intensity due to multiple reflection interference [26]. Raman also indicates significant substrate-induced strain in Cu-CVD graphene on PZT. In a study in accordance with an embodiment of the invention, G peaks of Cu-CVD graphene on PZT showed a noticeable red shift of ˜10 cm⁻¹ and broadening of full width at half maximum (FWHM), compared to CVD graphene on SiO₂. Using the G red shift, the PZT-induced strain was estimated to be ˜0.2% [27]. This implies that Cu-CVD graphene adapts to the polycrystalline surface of PZT after transfer, which may provide a lithography free approach for substrate engineering of local strain in graphene [28]. Note that by reducing the thickness of PZT to 120 nm, SLG and BLG are both optically and Raman distinguishable. However, thin PZT films usually have much larger leakage currents.

In a study in accordance with an embodiment of the invention, Quantum Hall Effect (QHE) measurements were used to determine the layer number of graphene. Typical QHE for single layer and bilayer CVD GFeFET on PZT were determined. The characteristic quantization sequences of (N+1/2)4e²/h for SLG and 4Ne²/h for BLG demonstrated the high quality of the Cu-CVD graphene. In FIG. 2, there is shown a wafer-scale array of Cu-CVD GFeFETs on PZT, in accordance with an embodiment of the invention. In a study in accordance with an embodiment of the invention, there were determined the typical resistance vs. gate voltage characteristics (R vs. V_{BG}) of GFeFETs without polarizing the PZT thin film by limiting V_{BG} below 1.1 V. In this linear dielectric regime, GFeFETs exhibit high on/off ratios exceeding 10 times with negligible R vs. V_{BG} hysteresis at ultra-low operating voltages previously known only from electrolyte gated samples. Hall measurements yield a linear doping vs. V_{bg} relation of n=αV_{BG}, with α=6.1×10¹² cm⁻² V⁻¹. This doping coefficient translates into a κ as high as 400 using the electrical displacement continuity equation at the graphene/PZT interface [5,10]. The high doping coefficient and κ were further confirmed by polarization measurement on the PZT thin film using the GFeFET as the top electrode. Compared to the previous literature report of GFeFETs on 400 nm epitaxial Pb(Zr_{0.2}Ti_{0.2})O₃ using multilayer graphene [29], the doping coefficient in CVD GFeFETs on PZT in accordance with an embodiment of the invention is almost 6 times higher. The difference in κ and doping coefficient is most likely due to the different compositions of the PZT thin films. Indeed, by substitutional doping of Pb by Lanthanum (La) and by fine tuning the ratio between Zr and Ti, a study in accordance with an embodiment of the invention has observed a much enhanced κ of ˜2000 (not shown). Note that GFeFETs on PZT have a very broad transition area near the Dirac point, manifested by significant deviation from linear n vs. V_{BG} relation below 3×10¹² cm⁻². This indicates the electron-hole puddle intensity of graphene on PZT is an order-of-magnitude higher than graphene on SiO₂. The strong charge inhomogeneity in graphene on PZT is likely due to the unpolarized surface dipoles of ferroelectric thin films.

In accordance with an embodiment of the invention, beyond the linear regime (V_{BG}>1.1V), the polarization of PZT leads to a pronounced hysteresis in R vs. V_{BG} (see FIG. 1A). The increasing Pᵣ not only increases the separation between the two resistance peaks, but also decreases the resistance minimum. This is because, in the polarized regime, dipole charges on the ferroelectric are aligned along the same direction and flip as a single domain. Such domain flipping of dipole charges effectively mimics the clustering of organic residues, which are expected to reduce long-range scattering in CVD graphene [30]. Indeed, after fully polarizing the PZT thin film, there is a factor of ˜2 enhancement in mobility to ˜4000 cm²V⁻¹ s⁻¹. The resistance hysteresis in FIG. 1A can be utilized for non-volatile memory and data storage applications [5]. Compared to the ferroelectric polymer used in Ref. [5], PZT allows for a significantly lower device operating voltage (<1V), much faster switching speed (<ns), and ultra-high endurance (10¹⁰ cycles). In a study in accordance with an embodiment of the invention, there was performed a fatigue test (±10V) of PZT thin films using a GFeFET as the top electrode. The nearly constant Pᵣ indicated that graphene can effectively stop metal in the top layer migrating into PZT, which is the main degradation mechanism of inorganic ferroelectric. A slight degradation during the first 10 k cycles was likely due to the low work function aluminum, which may contact exposed PZT surface during the wire bonding process.

In accordance with an embodiment of the invention, the combination of high-quality Cu-CVD graphene and functional substrates may be used to greatly speed up the studies of all graphene-based electronics. In a study in accordance with an embodiment of the invention there has been demonstrated the wafer-scale patterning and device operations of Cu-CVD graphene-ferroelectric field effect transistors on PZT substrates, integrating both transistor and non-volatile memory functionalities on the same chip by controlling the local ferroelectric polarization magnitude. In the linear regime of PZT, ultra-low-voltage operations of GFeFETs within ±1V have been demonstrated, which can be used as controlling transistors for addressing and reading/writing of memory unit cells. After polarizing PZT, the hysteretic switching of GFeFETs in accordance with an embodiment of the invention can be used for ultra-fast non-volatile data storage. To fully utilize the switching speed of PZT, a constant doping may be used to electrostatically “bias” the symmetrical ferroelectric doping hysteresis and create two distinct resistance states [29]. This can be realized by non-destructive charge-transfer doping via the deposition of low work function materials on the top surface of GFeFETs [31].

### Optical Control of Graphene-PZT Transistor

In another embodiment according to the invention, a wavelength-dependent modulation of graphene resistance is achieved in a low-voltage graphene/PZT transistor on a PZT substrate under photo-illumination. This allows an enhancement of the carrier doping to be achieved in the graphene sheet by the optical release of trapped interfacial charges. With the addition of a top polymer electrolyte layer on the device, reversible resistance states can also occur during light pulses. Applications include optically switchable non-volatile memory, broadband wavelength detector and optical-to-electrical data convertor.

The present day (opto-)-electronics industry relies heavily on silicon-based inorganic technology. Recently, graphene—a one atom thick layer with hexagonally arranged carbon lattice—has been the focus of several research efforts directed at expanding the scope of the electronics industry. The remarkable physical properties of graphene, such as the electric-field effect, ultra-high charge carrier mobility, high optical transparency and mechanical flexibility make it particularly suitable for replacing conventional technology in several niche applications [9, 32]. The tuning of charge-carrier concentration by means of electrostatic doping in graphene shifts the Fermi level such that the resistance increases as it approaches the Dirac point where carriers change from electrons to holes [19]. While several approaches for using the graphene field-effect transistor in chemical-and-bio-sensing have been explored, [4, 33] the low voltage, non-volatile memory applications have not received sufficient attention [6]. Low voltage and non-volatile applications are useful in information storage and offer the advantage of low power consumption by the elimination of the refresh rate as with the case of flash memory. These applications will be useful for developing novel portable electronic devices and enhancing the performance of mobile phones, mp3 players, portable PCs and memory devices.

In the field of optoelectronics, non-volatile applications are relevant for optically programmable memory devices, photo-detectors and wavelength-detectors. Ferroelectric materials (e.g., PZT) have high dielectric constant with hysteretic dielectric response to an applied electric field. Electrical control of graphene transistors on ferroelectric substrates can be used for non-volatile memory applications [6]. The controllable remnant polarization of PZT shifts the Fermi level of graphene towards the Dirac point or away, leading to the realization of high and low resistance states, respectively.

Ferroelectrics fabrication techniques have progressed competitively for miniaturization while maintaining their core properties [34]. Epitaxially-grown lead zirconate titanate (PZT) substrates have also shown to enhance the mobility of graphene to 10⁵ cm²V⁻¹ s⁻¹ in ambient conditions [35]. One approach to writing graphene/ferroelectric memories has been to use hysteresis loops of the ferroelectric to electrically write the “high” and “low” resistance states of the graphene channel, which, as those terms are used herein, correspond to the information storage bits of “1” and “0”, respectively.

In an embodiment according to the present invention, there is provided the optical control of the non-volatile, low-voltage operation of a Graphene-PZT transistor under photo-illumination in the ultra-violet, visible and/or infrared wavelength region (such as from about 200 nm to about 1 mm wavelength). This effect can be understood to result from the optical release of trapped interfacial charges at the graphene/PZT Schottky barrier interface allowing for modulation of ferroelectric-induced carrier doping in graphene. The influence of the switching of PZT-polarization under photo-illumination on graphene-based transistors, in accordance with an embodiment of the invention, can permit the optical writing of graphene/PZT memory devices. By choosing an appropriate wavelength of incident low-power optical pulse, a direct optical writing of the off state (“0”) and the on state (“1”) is possible for these memory devices. This high-resistance state persists even after illumination is turned off, implying a permanent change in the state of surface polarization for PZT. However, the device can be brought back to the low resistance “on” state by applying −2.5V (or another applied gate voltage) to the gate. Such device operations are useful for optical memory storage where a low power laser can be used to efficiently write the “on” or “off” state for individual memory devices in a large array, while a memory wipe or erase operation can be done with a single back gate sweep. The above phenomenon also has a strong wavelength-dependence, allowing for applications in broadband wavelength detectors and photo-detectors in the visible wavelength region.

Another embodiment of the invention comprises obtaining a reversible electrical response of graphene upon photo-illumination with a continuous optical pulse. This process allows an optical-to-electrical data conversion for the graphene/PZT memory device. In accordance with an embodiment of the invention, reversibility in the polarization changes of PZT following photo-illumination is produced, by using an additional top polymer electrolyte layer. During the processing of these devices, the higher mobility of positive Li+ ions in the polymer matrix results in the formation of a thin positively charged ionic layer adjacent to graphene [20]. The graphene gets n-doped when counter charges flow to balance the presence of ionic charges. In the presence of electrolyte ions, the interfacial built-in potential and the size of depletion zone in the ferroelectric are modified at the graphene/PZT Schottky barrier interface. The electric-field from the ions allows a return to the original polarization state when the incident optical pulse is in the off-state (or dark condition).

In yet another embodiment, incident blue-wavelength light on graphene/PZT transistors significantly enhances the maximum doping that can be achieved in graphene for a given value of voltage-range applied on the ferroelectric (it will be appreciated that other wavelengths can be used). This enhancement in the effective dielectric constant of PZT under photo-illumination with wavelengths close to the PZT band-gap represents a useful knob to achieve high-doping in graphene and to enhance the on-off ratios in graphene/ferroelectric memory devices.

The presently available graphene/ferroelectric memories only have an electrical control and readout. An embodiment according to the present invention allows for controlled manipulation of the resistance state by use of low power optical signals. This enhances the scope and application of these memory devices and can be used for the development of optical computers. A rapid writing process can be achieved, as follows. This procedure allows selected elements of the graphene/ferroelectric device array to be simultaneously exposed to incident optical pulse of selected wavelength (e.g., blue) to perform the write operation of “on” state. During this exposure, other devices can be protected from exposure by a pre-patterned mask array. These set of devices can then be simultaneously exposed to another wavelength (e.g., red) to achieve the “off” state while protecting the on-state devices from exposure by a complementary pre-patterned mask array. Besides this, when used in combination with the ferroelectric back-gate, much higher on-off ratios can be achieved in the active material (graphene) by optically enhancing the surface polarization state. In addition, the concept of optical-to-electrical data conversion will allow integration of optical and electrical components in a graphene/ferroelectric memory array, in accordance with an embodiment of the invention.

Several industrial applications of optically controlled graphene/ferroelectric memory devices in accordance with an embodiment of the invention include:

1. Optically programmable memory devices that do not require electrical voltage for writing the storage content.

2. Broadband photo-detectors operating in visible wavelength region.

3. Wavelength detectors in the visible wavelength region.

4. Next generation electronic devices with integrated optical and electrical components

5. Flexible optically controlled memory devices including flexible mobile phones, mp3 players and other storage media.

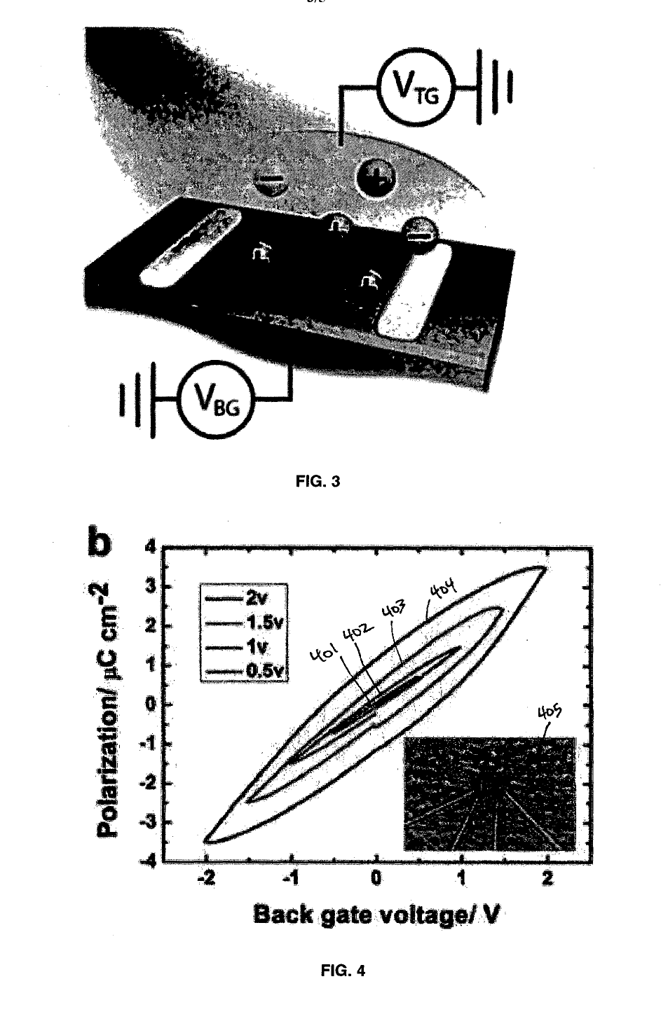

FIG. 3 is a schematic diagram of a graphene device in accordance with an embodiment of the invention, in two-terminal configuration. The typical length between contacts is 8 μm, and the width is 2 μm

FIG. 4 is a graph showing room temperature polarization measurements of a PZT substrate, in accordance with an embodiment of the invention. Measurements 401, 402, 403 and 404 at 0.5 V, 1V, 1.5V and 2V (respectively) are shown. An inset shows an optical image of a polymer electrolyte coated graphene/PZT device in accordance with an embodiment of the invention. The scale bar 405 is 10 μm.

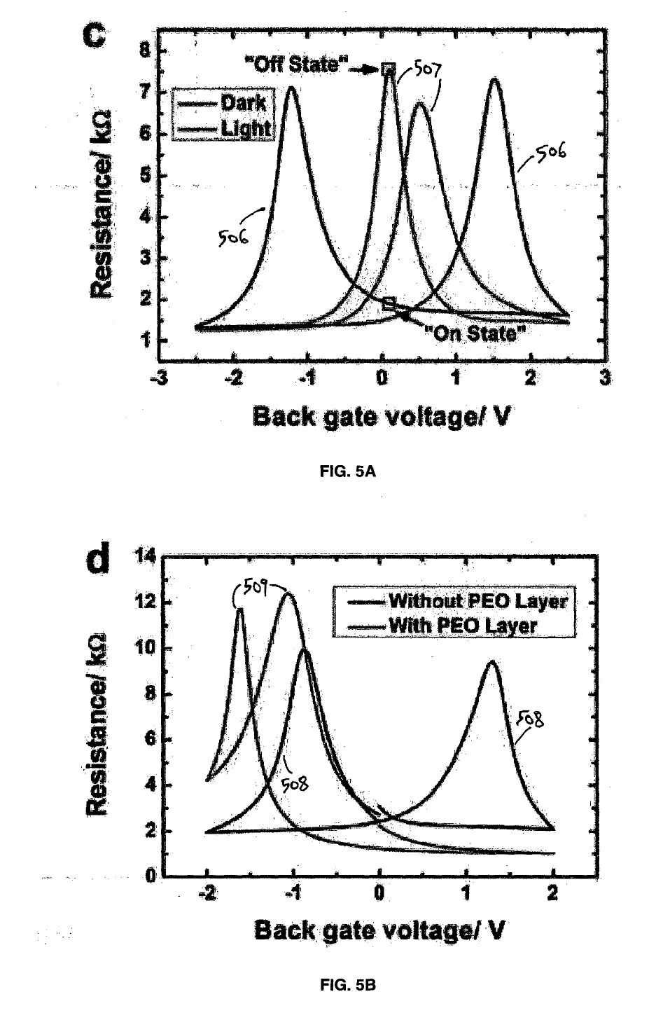

FIG. 5A is a graph showing resistance versus back gate voltage before addition of a polymer electrolyte in dark 506 and under white light photo-illumination 507, in accordance with an embodiment of the invention. FIG. 5B is a graph showing resistance versus back gate voltage (in dark) before 508 and after 509 addition of a polymer electrolyte.

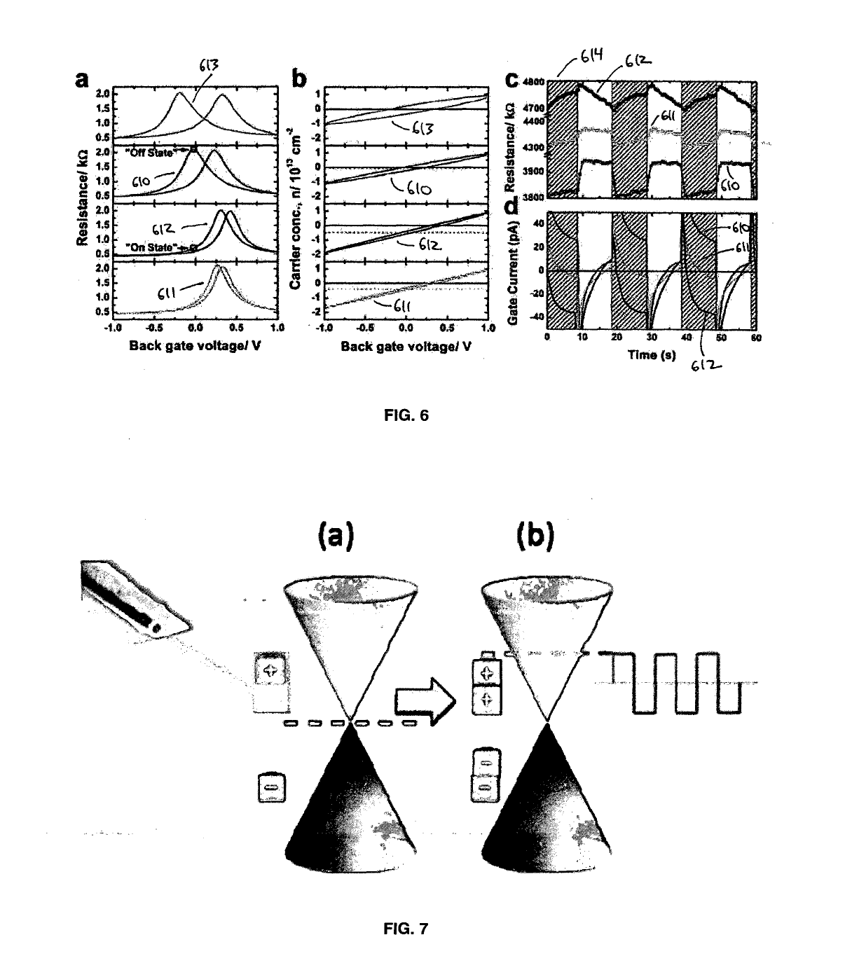

FIGS. 6A-6D are graphs showing red 610, green 611 and blue 612 wavelength illumination at an LED voltage of 4V, and measurement 613 in dark conditions, of a device in accordance with an embodiment of the invention. Hashed columns 614 indicate the duration of photo-illumination. FIG. 6A is a graph showing resistance versus back gate sweep for a graphene/PZT device in the dark and under photo-illumination of three different wavelengths (Red: 635 nm; Green: 565 nm; and Blue 466 nm), in accordance with an embodiment of the invention. FIG. 6B is a graph showing graphene carrier concentration versus V_{BG} in dark and under photo-illumination of three different wavelengths (Red: 635 nm; Green 565 nm; and Blue 466 nm), extracted from the data of FIG. 6A, in accordance with an embodiment of the invention. Dotted lines indicate zero polarization of PZT. FIG. 6C is a graph showing resistance versus time during pulsed photo-illumination (of three different wavelengths, viz., Red: 635 nm; Green: 565 nm; and Blue: 466 nm) of a device in accordance with an embodiment of the invention. FIG. 6D is a graph showing gate current versus time during pulsed photo-illumination (of three different wavelengths, viz., Red: 635 nm; Green: 565 nm; and Blue: 466 nm) of a device in accordance with an embodiment of the invention.

The foregoing FIGS. 3 through 6D are now described in more detail, based on a study that was performed in accordance with an embodiment of the invention. A schematic of the device geometry is shown in FIG. 3, where there was used a 120 nm thick PZT ferroelectric substrate covered with CVD-grown graphene and gold electrodes deposited by lithography (see Experimental section, below, for details of device structure). Graphene was then etched by an additional lithography process followed by oxygen plasma to create the channel within the electrodes region. The fabricated graphene transistor on PZT substrate was finally coated with an aqueous dispersion of polyethylene oxide (PEO) and lithium perchlorate that was drop cast on the device and bake-dried. Typical mobility for the graphene devices was about 750 cm²V⁻¹ s⁻¹. To obtain the electrical response of the device under photo-illumination, light-emitting diodes (LEDs) were used operating at different spectral ranges of the visible wavelength region. These LEDs have brightness of the order of 100 mcd, within the selected operating voltage range and the peak wavelengths of the red, green and blue LEDs were 635 nm (1.96 eV), 565 nm (2.20 eV) and 466 nm (2.67 eV), respectively. For the optical illumination of the graphene/PZT devices, the LEDs were positioned vertically at a distance of 4 mm from the sample. At the same maximum brightness, a rough estimate of the maximum incident power on the device is 13 mW cm⁻², 3 mW cm⁻² and 35 mW cm⁻² for red, green and blue LEDs, respectively. In addition to this wavelength-specific photo-illumination, focused white light from a halogen lamp source was also used for photo-illumination of the device under an optical microscope.

Polarization measurements were performed on these devices using a ferroelectric tester, in a study that was performed in accordance with an embodiment of the invention. FIG. 4 shows the hysteresis cycle of bulk polarization of PZT at different gate-voltage sweeps which does not undergo any significant change upon adding a layer of polymer electrolyte. For a gate-sweep of ±2 V, the remnant polarization is Pᵣ˜1.2 μC cm² while the maximum polarization is 3.5 μC cm⁻², which translates to a dielectric constant (κ) of ˜240. This provides the basis for the low-voltage gate operation of graphene/PZT transistor with a sizable hysteresis for a large on-off ratio. The resistance vs. back gate voltage of the graphene/PZT device (in the absence of the polymer electrolyte layer) measured in dark and under white light photo-illumination is plotted in FIG. 5A. A gate-voltage of as low as ±2 V is sufficient to switch between the “on” and “off” states of the non-volatile memory device whose working principle has been explained in a previous paper [10], the entire contents of which are hereby incorporated herein by reference. The hysteresis of graphene resistance curve becomes considerably narrower under photo-illumination which involves reduction of both the remnant polarization of PZT as well as the coercive voltage. As shown in FIG. 5A, at zero gate bias and prior to illumination, the device is in the low resistance “on” state and subsequent to the illumination, the resistance increases to the “off” state value. This high-resistance state persists even after illumination is turned off, implying a permanent change in the state of surface polarization for PZT. However, the device can be brought back to the low resistance “on” state by applying −2.5 V to the gate.

The addition of the polymer electrolyte layer results in graphene being heavily n-doped, as shown in FIG. 5B, in accordance with an embodiment of the invention. This is due to the higher mobility of the positive Li+ ions in the polymer matrix, which assembles them in the vicinity of the graphene surface during the processing step. This configuration of the device results in a strong interfacial electric field between the electrolyte ions residing on the surface of graphene and the polarized PZT underneath graphene.

In a study in accordance with an embodiment of the invention, the changes in graphene/PZT device characteristics under photoillumination with wavelengths in different regions of the visible spectrum were investigated. In the absence of an applied gate bias, reproducible resistance changes were observed upon illumination of the device. This allows memory write operations to be realized by purely optical means for the graphene devices without a gate. For V_{g}=0 V, red wavelength illumination will write an “off” state while blue wavelength illumination will write an “on” state, as shown in FIG. 6A. Resistance vs. V_{BG} measurements were performed in the sequence of dark, red, blue and green wavelength illumination, followed by a sweep in dark conditions—the latter eventually reproduced the data in the original curve under dark conditions. A substantial reduction in the width of the voltage plateau at CNP upon illumination with green and blue wavelengths points to a remarkable increase in the polarization. A rough estimate of the voltage dependence of carrier concentration in graphene under various photo-illumination conditions can be extracted from the data in FIG. 6A and these extracted curves are plotted in FIG. 6B. From the gradient of the n vs. V_{BG} curve, a substantial increase in polarization can be inferred for decreasing wavelengths. The maximum change in polarization can be associated with the blue wavelength region of the visible spectrum. Photo-illumination of the device with the red wavelength region results in negligible changes in the polarization state when compared to the curve measured in dark conditions. The wavelength dependent response, suggests possible applications in broadband wavelength detectors.

In addition to the above-discussed polarization-related permanent changes in the resistance of graphene upon photo-illumination of the device, it is also possible to induce reversible changes in graphene resistance under low frequency (0.05 Hz) optical pulses of different wavelengths, in accordance with an embodiment of the invention. This may be achieved by introducing a thin polymer electrolyte layer on top of the graphene device. The presence of the polymer-electrolyte layer partially reduces the intensity at the graphene/PZT interface. More importantly, the photo-illumination induced resistance changes in graphene are found to be reversible when this electrolyte layer is present. A time-dependent plot of the graphene resistance is shown in FIG. 6C and the resistance changes faithfully follow the photo-illumination cycle. The resistance varies reversibly between two levels depending on the on and off state of the optical pulse. The maximum response (ΔR/R) as well as the shortest transition time is both obtained in the red wavelength region of the optical pulse.

In a study in accordance with an embodiment of the invention, to obtain insight on the reversibility of the photo-induced resistance change in the presence of the electrolyte, there was investigated the photocurrents generated at the interface for the electrolyte/graphene/PZT device under pulsed optical illumination. The sign of the generated photocurrents are positive or negative depending on the positive or negative polarization of the ferroelectric. Under red (blue) illumination, the steady-state photocurrent is positive (negative) while in the dark state, it tends towards zero, as shown in FIG. 6D. In addition to the above, a large transient increase in the photocurrent is observed upon switching between the dark and photo-illuminated conditions, and this transient current is quite independent of the optical wavelength.

### Experimental Device Fabrication:

In an experiment in accordance with an embodiment of the invention, Pb(Zr_{0.7}, Ti_{0.3})O₃ (PZT) films were prepared by sol-gel method on a sandwiched hetero-structure comprising of layers of 120 nm Pt, 20 nm Ti, 300 nm SiO₂ on Si <100>substrate. CVD graphene grown on copper foil consisting of predominantly single layer sheet with scattered bilayers was spin coated with PMMA and etched in ammonium persulfate solution. Wet transfer of CVD graphene to PZT substrate was followed by the removal of PMMA using anisole followed by rinse in acetone and iso-propyl alcohol [3]. Graphene was isolated into (0.4 mm)² squares by an etch mask created by standard electron beam lithography (EBL) and oxygen plasma etching followed by acetone removal of PMMA. Graphene was contacted by a subsequent EBL step followed by the thermal evaporation of 3 nm Cr/35 nm of Au lift off in acetone. A final etch was done to isolate a graphene channel between the contacts. The length and width of the graphene channel were 8 μm and 2 μm, respectively. An aqueous dispersion of polyethylene oxide: lithium perchlorate (1:0.12) was drop-cast on the device and baked dry on a hot plate at 80° C. for 5 mins.

### Electrical Measurement:

In an experiment in accordance with an embodiment of the invention, aluminum wire leads were connected to the Au contacts by silver epoxy. All measurements were done in two terminal configuration. A Stanford SR830 lock-in amplifier sourced a constant current of 100 nA and a phase-sensitive detection of the sourcedrain voltage was also recorded. The back gate bias was applied and the gate current was monitored using Keithley 6430 sub-femtoamp sourcemeter. A function generator (DS 345) was used to source a square-wave pulsed output from the light-emitting diodes. Polarization measurements were performed using the Radiant Precision LC Ferroelectric tester.

FIGS. 7A and 7B are schematic diagrams illustrating the concept of optically programmable graphene/PZT memory devices in accordance with an embodiment of the invention. The dotted line in FIG. 7A represents the position of the Fermi level of graphene with respect to the energy band diagram. Optical pulses are used to modulate the interfacial properties of graphene/PZT, and in particular, as shown in FIG. 7B, to modulate the polarization state of PZT, thereby shifting the Fermi level of graphene. This change in the Fermi level of graphene is translated into a switch between the high and low resistance states, thereby allowing optical manipulation of storage data.

### REFERENCES

1. Novoselov, K. S., A. K. Geim, et al. (2004). “Electric field effect in atomically thin carbon films.” Science 306(5296): 666-669.
2. Lin, Y. M., C. Dimitrakopoulos, et al. (2010). “100-GHz Transistors from Wafer-Scale Epitaxial Graphene.” Science 327(5966): 662-662.
3. Bae, S., H. Kim, et al. (2010). “Roll-to-roll production of 30-inch graphene films for transparent electrodes.” Nature Nanotechnology 5(8): 574-578.
4. Kim, B. J., H. Jang, et al. (2010). “High-Performance Flexible Graphene Field Effect Transistors with Ion Gel Gate Dielectrics.” Nano Letters 10(9): 3464-3466.
5. Zheng, Y., G. X. Ni, et al. (2009). “Gate-controlled nonvolatile graphene-ferroelectric memory.” Applied Physics Letters 94(16): 163505
6. Zheng, Y. and et al. (2011). “Wafer-scale graphene/ferroelectric hybrid devices for low-voltage electronics.” EPL (Europhysics Letters) 93(1): 17002.
7. Schwierz, F. (2010). “Graphene transistors.” Nature Nanotechnology 5(7): 487-496.
8. Y. Zheng, G. X. Ni, C. T. Toh and B. Özyilmaz: (Licensed by NUS), PCT PCT/SG2009/000352, filed Sep. 23, 2009, entitled “Graphene memory cell and fabrication methods thereof”
9. Geim A. K. and Novoselov K. S., Nat. Mater., 6 (2007) 183; Geim A. K., Science, 324 (2009) 1530.
10. Zheng Y. et al., Phys. Rev. Lett., 105 (2010) 166602.
11. Li X. S. et al., Science, 324 (2009) 1312.
12. Lee S., Lee K. and Zhong Z., Nano Lett., 10 (2010) 4702.
13. Dean C. R. et al., Nat. Nanotechnol., 5 (2010) 722.
14. Giovannetti G. et al., Phys. Rev. B, 76 (2007) 073103.
15. Heersche H. B. et al., Nature, 446 (2007) 55.
16. Elias D. C. et al., Science, 323 (2009) 610.
17. Michetti P., Recher P. and Iannaccone G., Nano Lett., 10 (2010) 4463.
18. Vrejoiu I. et al., Adv. Mater., 18 (2006) 1657.
19. Castro Neto A. H. et al., Rev. Mod. Phys., 81 (2009) 109.
20. Pachoud A. et al., EPL, 92 (2010) 27001.
21. Savini G., Ferrari A. C. and Giustino F., Phys. Rev. Lett., 105 (2010) 037002.
22. Castro E. V. et al., Phys. Rev. Lett., 99 (2007) 216802.
23. Zhang Y. B. et al., Nature, 459 (2009) 820; Xia F. N., Farmer D. B., Lin Y. M. and Avouris P., Nano Lett., 10 (2010) 715.
24. Li X. S. et al., Nano Lett., 9 (2009) 4359.
25. Lee Y. et al., Nano Lett., 10 (2010) 490.
26. Wang Y. Y. et al., Appl. Phys. Lett., 92 (2008) 043121; Yoon D. et al., Phys. Rev. B, 80 (2009) 125422.
27. Mohiuddin T. M. G. et al., Phys. Rev. B, 79 (2009) 205433.
28. Pereira V. M. and Castro Neto A. H., Phys. Rev. Lett., 103 (2009) 046801.
29. Hong X. et al., Phys. Rev. Lett., 102 (2009) 136808; Appl. Phys. Lett., 97 (2010) 033114.
30. Katsnelson M. I., Guinea F. and Geim A. K., Phys. Rev. B, 79 (2009) 195426.
31. Chen Z. Y. et al., Appl. Phys. Lett., 96 (2010) 213104.
32. S. Bae, H. Kim, Y. Lee, X. Xu, J.-S. Park, Y. Zheng, J. Balakrishnan, T. Lei, H. Ri Kim, Y. I. Song, Y.-J. Kim, K. S. Kim, B. Özyilmaz, J.-H. Ahn, B. H. Hong, S. Iijima, Nature Nanotechnology 2010, 5, 574.
33. F. Sehedin, A. K. Geim, S. V. Morozov, E. W. Hill, P. Blake, M. I. Katsnelson, K. S. Novoselov, Nature Materials 2007, 6, 652.
34. H. Han, Y. Kim, M. Alexe, D. Hesse, W. Lee, Advanced Materials 2011, 23, 4599.
35. X. Hong, A. Posadas, K. Zou, C. H. Ahn, J. Zhu, Physical Review Letters 2009, 102, 136808.

The teachings of all patents, published applications and references cited herein are incorporated by reference in their entirety.

While this invention has been particularly shown and described with references to example embodiments thereof, it will be understood by those skilled in the art that various changes in form and details may be made therein without departing from the scope of the invention encompassed by the appended claims.

What is claimed is:

1. A graphene ferroelectric device, the device comprising:
a graphene transistor channel; and
a ferroelectric gate of the graphene transistor channel, the ferroelectric gate comprising a linear polarization at a first applied gate voltage less than a threshold voltage, and a hysteretic polarization at a second applied gate voltage greater than the threshold voltage.

2. A graphene ferroelectric device according to claim 1, wherein the ferroelectric gate comprises lead zirconate titanate.

3. A graphene ferroelectric device according to claim 2, wherein the lead zirconate titanate comprises Pb(Zr_{0.3}Ti_{0.7})O₃.

4. A graphene ferroelectric device according to claim 1, wherein the threshold voltage is at an electric field of about 3 MV/m.

5. A graphene ferroelectric device according to claim 1, wherein the graphene transistor channel and the ferroelectric gate comprise a transistor at the first applied gate voltage less than the threshold voltage and comprise a non-volatile memory at the second applied gate voltage greater than the threshold voltage.

6. A graphene ferroelectric device according to claim 1, wherein the graphene transistor channel and the ferroelectric gate comprise a transistor at the first applied gate voltage less than the threshold voltage, the graphene transistor channel and the ferroelectric gate being configured to control at least one memory array.

7. A graphene ferroelectric device according to claim 6, the memory array comprising at least one other graphene transistor channel and a ferroelectric gate of the other graphene transistor channel, the ferroelectric gate of the other graphene transistor channel comprising lead zirconate titanate, the at least one other graphene transistor channel and ferroelectric gate comprising a non-volatile memory at the second applied gate voltage greater than the threshold voltage.

8. A graphene ferroelectric device according to claim 7, wherein the graphene transistor channel and the at least one other graphene transistor channel are included in an array of a plurality of graphene transistor channels on a ferroelectric substrate.

9. A graphene ferroelectric device according to claim 7, wherein the device is configured to operate as a sensor.

10. A graphene ferroelectric device according to claim 1, wherein at least a portion of the device is transparent.

11. A graphene ferroelectric device according to claim 1, wherein at least a portion of the device is flexible.

12. A graphene ferroelectric device according to claim 1, further comprising a flexible and transparent substrate.

13. A graphene ferroelectric device according to claim 1, wherein the graphene transistor channel comprises a single layer of graphene.

14. A graphene ferroelectric device according to claim 1, comprising an on/off current ratio of at least about 10.

15. A graphene ferroelectric device according to claim 1, the device being configured to be dynamically switched by a gate bias voltage between operating as a transistor and operating as a non-volatile memory.

16. A graphene ferroelectric device according to claim 1, wherein the device is configured to undergo optical switching of the graphene transistor channel between a high resistance state and a low resistance state in response to photoillumination of the device.

17. A graphene ferroelectric device according to claim 1, further comprising a polymer electrolyte layer.

18. A graphene ferroelectric device according to claim 17, wherein the device is configured to enter a reversible resistance state in response to photoillumination.

19. A graphene ferroelectric device according to claim 16, wherein the photoillumination comprises light of a wavelength from the group consisting of an ultraviolet wavelength, a visible wavelength and an infrared wavelength.

20. A graphene ferroelectric device according to claim 1, wherein a resistance of the graphene transistor channel is configured to change in response to a wavelength of photoillumination of the device.

21. A graphene ferroelectric device according to claim 20, wherein the resistance of the graphene transistor channel is further configured to return to a low resistance state in response to an applied gate voltage.

22. A graphene ferroelectric device according to claim 1, wherein the device comprises a device from the group consisting of: an optically switchable non-volatile memory; a broadband wavelength detector and an optical-to-electrical data convertor.

23. A method of controlling the resistance state of a memory device, the method comprising:
exposing at least one first selected element of the memory device, the at least one first selected element comprising at least one first graphene ferroelectric device, to photoillumination of a first selected wavelength, thereby performing a write operation of an on resistance state of the memory device, the at least one first graphene ferroelectric device comprising a first graphene transistor channel and a first ferroelectric gate of the first graphene transistor channel, the first ferroelectric gate comprising lead zirconate titanate;
while exposing the at least one first selected element to the photoillumination of the first selected wavelength, protecting at least one second selected element of the memory device from exposure to the photoillumination at the first selected wavelength, the at least one second selected element comprising at least one second graphene ferroelectric device comprising a second graphene transistor channel and a second ferroelectric gate of the second graphene transistor channel, the second ferroelectric gate comprising lead zirconate titanate; and
exposing the at least one second selected element of the memory device to photoillumination of a second selected wavelength, while protecting the at least first selected element from exposure to the photoillumination of the second selected wavelength, thereby achieving an off resistance state of the memory device.
